(19) United States
(12) Patent Application Publication
(10) Pub. No.: US 2026/0013232 A1
(43) Pub. Date: Jan. 8, 2026

(54) PIXEL ARRAY SUBSTRATE AND MANUFACTURING METHOD THEREOF

(71) Applicant: HannStar Display Corporation, Taipei City (TW)

(72) Inventors: Li Fang Chiu, Taipei City (TW); Min Sheng Chiu, Taipei City (TW)

(73) Assignee: HannStar Display Corporation, Taipei City (TW)

(21) Appl. No.: 18/902,990

(22) Filed: Oct. 1, 2024

(30) Foreign Application Priority Data
Jul. 4, 2024 (TW) 113125075

(51) Int. Cl. H01L 27/12

(52) U.S. Cl. CPC H10D 86/60; H10D 86/021; H10D 86/441

(57) ABSTRACT

A manufacturing method of a pixel array substrate is provided. The manufacturing method of the pixel array substrate includes forming a sacrificial layer on a substrate, forming a metal stack layer on the sacrificial layer, using a dry etching process to remove part of the metal stack layer and part of the sacrificial layer and forming a plurality of gate lines and a plurality of protruding patterns, and performing a plasma treatment process on surfaces of the gate lines and the protruding patterns using a reactive gas. The metal stack layer includes a first titanium layer, an aluminum layer and a second titanium layer. The protruding patterns are respectively aligned with the gate lines. A pixel array substrate produced by using the manufacturing method of the pixel array substrate is also provided.

### CROSS-REFERENCE TO RELATED APPLICATION

This application claims the priority benefit of Taiwan application serial no. 113125075, filed on Jul. 4, 2024. The entirety of the above-mentioned patent application is hereby incorporated by reference herein and made a part of this specification.

### BACKGROUND

### Technical Field

The disclosure relates to a substrate and a manufacturing method thereof, and more particularly, to a pixel array substrate and manufacturing method thereof.

### Description of Related Art

In a current pixel array substrate, in order to improve the conductivity of a metal stack layer directly formed on a glass substrate, the metal stack layer may be composed of at least a titanium layer and an aluminum layer. However, after the etching process of the metal stack layer, the etching gases tend to remain on the surface of the circuit structure formed by patterning the metal stack layer, causing subsequent metal corrosion problems.

In order to solve the above problems, a process method utilizing high-power plasma to treat the surface of the circuit structures is proposed. Such an approach, however, can result in the photoresist pattern used in the etching process not being completely removed during the subsequent photoresist removal process, leaving residues on the circuit structure.

### SUMMARY

The disclosure provides a manufacturing method of a pixel array substrate, which can avoid the problems of metal corrosion and photoresist residue.

The disclosure provides a pixel array substrate with better process yield and reliability.

A manufacturing method of a pixel array substrate in the disclosure includes forming a sacrificial layer on a substrate, forming a metal stack layer on the sacrificial layer, using a dry etching process to remove part of the metal stack layer and part of the sacrificial layer and forming a plurality of gate lines and a plurality of protruding patterns, and performing a plasma treatment process on surfaces of the gate lines and the protruding patterns using a reactive gas. The metal stack layer includes a first titanium layer, an aluminum layer and a second titanium layer. The protruding patterns are respectively aligned with the gate lines.

A pixel array substrate in the disclosure includes a substrate, a plurality of gate lines, and a sacrificial layer. Each of the gate lines includes a first titanium layer, an aluminum layer and a second titanium layer sequentially stacked on the substrate. The sacrificial layer is disposed between the substrate and each of the gate lines and has a plurality of protruding patterns aligned with the gate lines.

Based on the above, in a manufacturing method of a pixel array substrate according to an embodiment of the disclosure, a sacrificial layer is formed between a metal stack layer and the substrate. Therefore, a dry etching process used to remove part of the metal stack layer also further remove part of the sacrificial layer. Accordingly, the amount of residual etching gas can be significantly reduced after performing a plasma treatment process on surfaces of the formed gate lines and protruding patterns, thereby avoiding the problems of metal corrosion and photoresist residue. In other words, the pixel array substrate produced by the aforementioned method may have higher process yield and reliability.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic front view of a pixel array substrate according to an embodiment of the disclosure.

FIG. 2 is a schematic cross-sectional view of a display panel according to an embodiment of the disclosure.

FIG. 3 and FIG. 4 are flow charts of a manufacturing method of the pixel array substrate of FIG. 2.

FIG. 5A to FIG. 5E are schematic cross-sectional views of the manufacturing process of the pixel array substrate of FIG. 2.

### DESCRIPTION OF THE EMBODIMENTS

The aforementioned and other technical contents, features, and effects of the disclosure will be clearly presented in the following detailed description of a preferred embodiment with reference to the accompanying drawings. The directional terms mentioned in the following embodiments, such as up, down, left, right, front, or back, are merely references to the directions in the accompanying drawings. Therefore, the directional terms used are for explanatory purposes and are not intended to limit the present invention.

Exemplary embodiments of the disclosure are now described in detail with reference to the accompanying drawings. Wherever possible, the same reference numerals are used in the drawings and the description to refer to the same or similar parts.

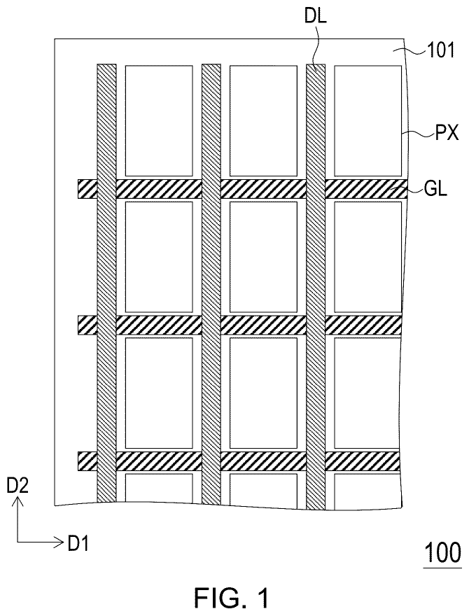

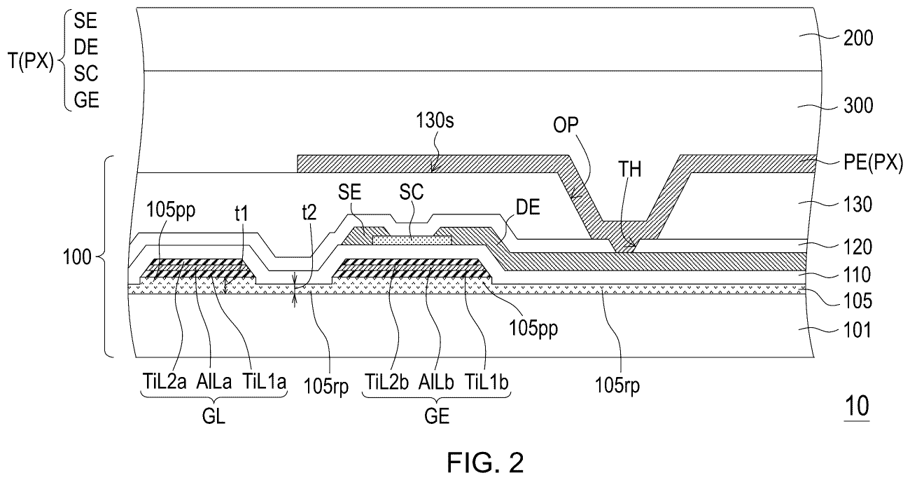

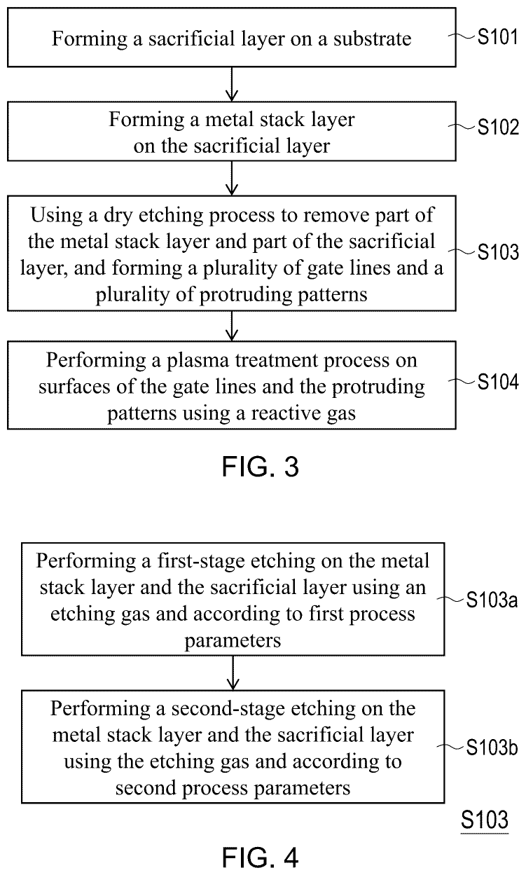

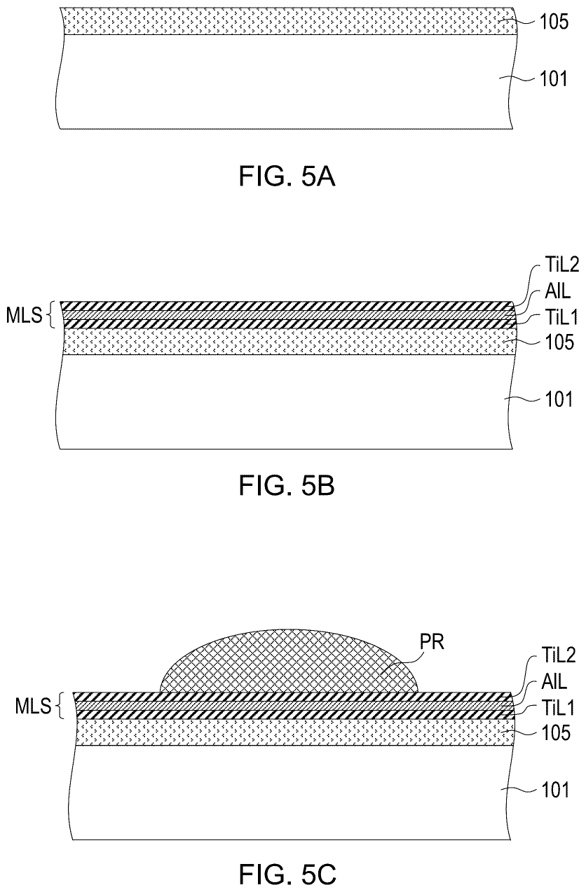

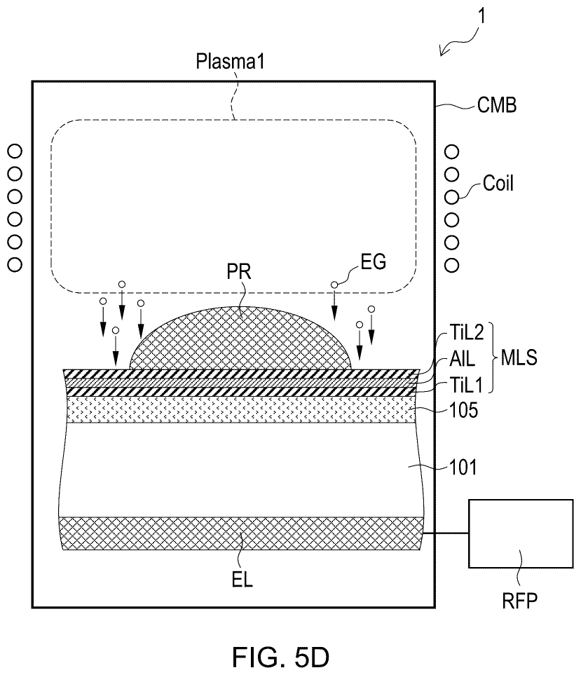

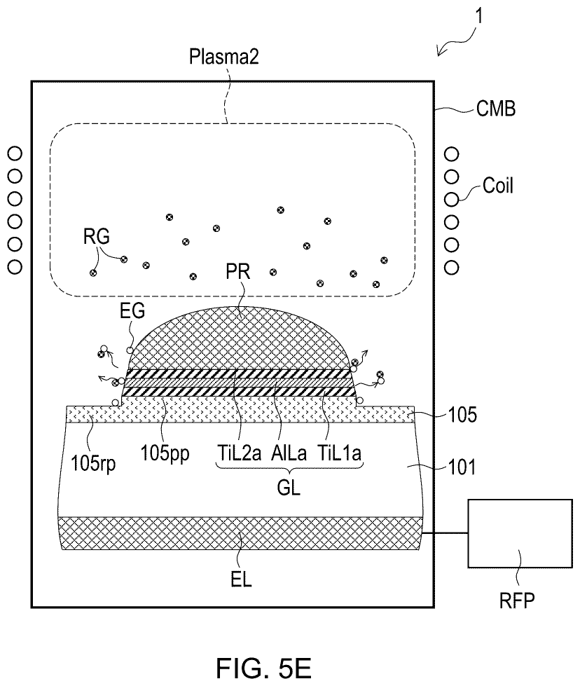

FIG. 1 is a schematic front view of a pixel array substrate according to an embodiment of the disclosure. FIG. 2 is a schematic cross-sectional view of a display panel according to an embodiment of the disclosure. FIG. 3 and FIG. 4 are flow charts of a manufacturing method of the pixel array substrate of FIG. 2. FIG. 5A to FIG. 5E are schematic cross-sectional views of the manufacturing process of the pixel array substrate of FIG. 2.

Referring to FIG. 1 and FIG. 2, a pixel array substrate 100 includes a substrate 101, a plurality of data lines DL, a plurality of gate lines GL and a plurality of pixel structures PX. In the embodiment, the data lines DL are, for example, spaced apart along a direction D1 and extend in a direction D2, and the gate lines GL, for example, are spaced apart along the direction D2 and extend in the direction D1. That is, the plurality of data lines DL and the plurality of gate lines GL intersect with each other and define a plurality of pixel areas. The plurality of pixel structures PX are respectively disposed in the plurality of pixel areas, and are each electrically connected to a gate line GL and a data line DL. More specifically, the pixel structures PX may be arranged in an array on the substrate 101, for example, arranged in multiple columns and rows along the direction D1 and the direction D2.

In detail, the pixel structure PX includes an active device T and a pixel electrode PE. In the embodiment, the method of forming the active device T may include the following steps: sequentially forming a gate electrode GE, a gate insulating layer 110, a semiconductor pattern SC, a source electrode SE and a drain electrode DE on the substrate 101. The semiconductor pattern SC overlaps the gate electrode GE. The source electrode SE and the drain electrode DE overlap the semiconductor pattern SC and are in electrical contact with two different regions of the semiconductor pattern SC. In the embodiment, the gate electrode GE of the active device T may be selectively disposed below the semiconductor pattern SC to form a bottom-gate thin film transistor (bottom-gate TFT), but the disclosure is not limited thereto. In other embodiments, the gate electrode of the active device may also be selectively disposed above the semiconductor pattern to form a top-gate thin film transistor (top-gate TFT).

It should be noted that the gate GE electrode, the source electrode SE, the drain electrode DE, the semiconductor pattern SC and the gate insulating layer 110 may be realized by any gate electrode, any source electrode, any drain electrode, any semiconductor pattern and any gate insulating layer for a display panel that is well known to those skilled in the art, and the gate electrode GE, the source electrode SE, the drain electrode DE, the semiconductor pattern SC and the gate insulating layer 110 may be formed by any method that is well known to those skilled in the art, so it will not be described in detail here.

In the embodiment, the active device T is covered with a passivation layer 120 and a planarization layer 130. The material of the planarization layer 130 may be an organic material, and the material of the passivation layer 120 may be an inorganic material. The passivation layer 120 is located between the planarization layer 130 and a metal layer (such as the source electrode SE and drain electrode DE of the active device T) to prevent poor adhesion between the planarization layer 130 and the metal layer, which causes them to peel from each other, but the disclosure is not limited thereto. The pixel electrode PE of the pixel structure PX is disposed on a surface 130s of the planarization layer 130 facing away from the substrate 101, and is electrically connected to the drain electrode DE of the active device T through an opening OP of the planarization layer 130 and the through hole TH of the passivation layer 120.

In the embodiment, the gate electrode GE and the gate line GL of the active device T may be the same film layer, and the film layer is a metal stack layer. For example, the gate line GL may include a first titanium layer TiL1a, an aluminum layer AlLa, and a second titanium layer TiL2a sequentially stacked on the substrate 101, and the gate electrode GE may include a first titanium layer TiL1b, an aluminum layer AlLb, and a second titanium layer TiL2b sequentially stacked on the substrate 101. Wherein, a thickness of each of the first titanium layer and the second titanium layer may be greater than or equal to 200 angstroms, and a thickness of the aluminum layer may be greater than or equal to 1000 angstroms, but the disclosure is not limited thereto.

It is particularly important to note that the pixel array substrate 100 is further provided with a sacrificial layer 105 between the substrate 101 and the gate line GL (or gate electrode GE). The sacrificial layer 105 has a plurality of protruding patterns 105pp respectively aligned with the plurality of gate lines GL and the plurality of gates GE and residual portions 105rp extending from the protruding patterns 105pp. Preferably, the percentage of a thickness t2 of the residual portion 105rp to a thickness t1 of the protruding pattern 105pp is less than or equal to 20%. The material of the sacrificial layer 105 includes SiNₓ or SiO₂.

It should be noted first that the configuration of the sacrificial layer 105 between the substrate and the metal stack layer formed by the aforementioned two titanium layers and an aluminum layer may effectively reduce the residual amount of etching gas on the surface of the formed circuit structures (for example, the gate lines GL and the gate electrode GE, but the disclosure is not limited thereto) during a dry etching process of the metal stack layer, and thereby avoiding the problems of metal corrosion and photoresist residue.

The following will exemplarily describe a manufacturing method of the gate lines GL on the pixel array substrate 100. Referring to FIG. 3 and FIG. 5A, first, forming a sacrificial layer 105 on a substrate 101 (i.e., step S101). In the embodiment, a film thickness of the sacrificial layer 105 is not less than 250 angstroms. Next, as shown in FIG. 3 and FIG. 5B, a metal stack layer MLS is formed on the sacrificial layer 105 (i.e., step S102). In the embodiment, the step of forming the metal stack layer MLS may include sequentially forming a first titanium layer TiL1, an aluminum layer AlL, and a second titanium layer TiL2 on the substrate 101.

Referring to FIG. 3, FIG. 5C to FIG. 5E, after completing the film formation of the metal stack layer MLS, using a dry etching process to remove part of the metal stack layer MLS and part of the sacrificial layer 105, and forming a plurality of gate lines GL and a plurality of protruding patterns 105pp (i.e., step S103). For example, in the embodiment, the steps of the dry etching process include forming a photoresist pattern PR on the metal stack layer MLS (as shown in FIG. 5C) and etching the metal stack layer MLS using an etching gas EG (as shown in FIG. 5D).

In the embodiment, the etching process of the metal stack layer MLS is performed using a dry etching equipment 1. The dry etching equipment 1 is, for example, an etching equipment using inductively coupled plasma (ICP) as a plasma source, and includes, for example, a chamber CMB, an electrode coil Coil, and a lower electrode plate EL. The electrode coil Coil may be electrically connected to a radio frequency (RF) power source (not shown), and is used to form high-density plasma in the chamber CMB. The lower electrode plate EL disposed in the chamber CMB is electrically coupled to another RF power source RFP, and is used to provide an etching bias.

During the etching process, the substrate 101 and the metal stack layer MLS and the sacrificial layer 105 formed thereon are suitable for being placed on the lower electrode plate EL. The etching gas EG forms ionized etching gas ions (i.e., plasma Plasma 1) after entering the chamber CMB and being dissociated in a space surrounded by the electrode coil Coil. The bias control of the lower electrode plate EL allows the ionized etching gas EG to have anisotropic etching capabilities (as shown in FIG. 5D). In the embodiment, the etching gas EG includes Cl₂, for example.

In the embodiment, step S103 of removing part of the metal stack layer MLS and part of the sacrificial layer 105 using the dry etching process may be divided into two stages. In these two stages, the dry etching equipment 1 is set with different process parameters. Referring to FIG. 3, FIG. 4 and FIG. 5C to FIG. 5D, for example, first, performing a first-stage etching on the metal stack layer MLS and the sacrificial layer 105 using an etching gas EG and according to first process parameters (i.e., step S103a), where the first process parameters include a first chamber pressure, a first bias power and a first etching time. Next, performing a second-stage etching on the metal stack layer MLS and the sacrificial layer 105 using the etching gas EG and according to second process parameters (i.e., step S103b), where the second process parameters include a second chamber pressure, a second bias power and a second etching time. It should be noted that the second bias power set during the second-stage etching is less than the first bias power set during the first-stage etching, the second chamber pressure is less than the first chamber pressure, and the second etching time is less than the first etching time.

It is particularly noted that the first-stage etching is mainly for patterning the metal stack layer MLS, for example: removing part of the second titanium layer TiL2, part of the aluminum layer AlL and part of the first titanium layer TiL1 to form the second titanium layer TiL2a, the aluminum layer AlLa, and the first titanium layer TiL1a, respectively. The second-stage etching primarily adjusts the profile of the etched sidewalls of the metal stack layer MLS formed after the first-stage etching (e.g., the angle of inclination of the sidewall surfaces of the second titanium layer TiL2a, the aluminum layer AlLa, and the first titanium layer TiL1a in FIG. 5E).

On the other hand, after the etching gas EG has reacted with the portion of the metal stack layer MLS to be removed, the excess etching gas EG will further react with part of the sacrificial layer 105 and forming reaction products which are then discharged out of the chamber CMB. In this way, it can be avoided that a large amount of unreacted etching gas EG is adsorbed on the surface of the formed circuit structure (e.g., the gate lines GL), causing subsequent metal corrosion problems.

Therefore, after the dry etching process is completed, in addition to removing part of the metal stack layer MLS to form a plurality of gate lines GL, part of the sacrificial layer 105 is also removed to form a plurality of protruding patterns 105pp respectively aligned with the gate lines GL.

Referring to FIG. 3 and FIG. 5E, after the dry etching process of the metal stack layer MLS is completed, performing a plasma treatment process on the surfaces of the plurality of gate lines GL and the plurality of protruding patterns 105pp using a reactive gas RG (i.e., step S104). The reactive gas RG includes, for example, CF₄ and O₂. In this step, the reactive gas RG entering the chamber CMB is dissociated in a space surrounded by the electrode coil Coil to form ionized reactive gas ions (i.e., plasma Plasma2).

The ionized reactive gas RG reacts with the surface of the gate line GL, the sacrificial layer 105 or the photoresist pattern PR or the etching gas EG adsorbed thereon and forms reaction products (such as Al₃O₂, AlCl₃ or AlF₃) which are then discharged out of the chamber CMB. In this way, the risk of metal corrosion in the gate lines GL due to the residual etching gas EG may be further reduced, which helps to improve the production yield and reliability of the pixel array substrate 100. From another point of view, due to the configuration of the sacrificial layer 105, the power of power source used to form the plasma in the plasma treatment process of step S104 does not need to be very high. Therefore, it avoids the problem of the photoresist pattern PR deteriorating and not being completely removed after being treated with plasma generated by high power of power source. In other words, the configuration of the sacrificial layer 105 may also increase the process margin of the plasma treatment process (i.e., step S104).

At this point, the fabrication of the gate lines GL on the pixel array substrate 100 is completed. It should be noted that since the gate electrode GE of the active device T and the gate line GL are formed in the same film layer, the illustration of the process forming the gate electrode GE of the active device T in FIG. 2 is omitted in FIG. 5A to FIG. 5E for clarity.

In the embodiment, the pixel array substrate 100 is suitable for being assembled with another substrate 200, and a liquid crystal layer 300 is filled between them to form a display panel 10. That is, the pixel array substrate 100 of the embodiment may be used as one of the substrates of a liquid crystal display panel. For example, the substrate 200 may be provided with a color filter layer (not shown) and/or a common electrode layer (not shown), but the disclosure is not limited thereto. In some embodiments, the common electrode layer may be disposed on the pixel array substrate 100. The electric field generated between the common electrode layer and the pixel electrode PE is suitable for driving a plurality of liquid crystal molecules (not shown) of the liquid crystal layer 300 to rotate to form an alignment state corresponding to the direction and intensity of the electric field. By changing the alignment state of these liquid crystal molecules, the polarization state of the light passing through the liquid crystal layer 300 is changed to form a light emission brightness corresponding to the alignment state.

To sum up, in a manufacturing method of a pixel array substrate according to an embodiment of the disclosure, a sacrificial layer is formed between a metal stack layer and the substrate. Therefore, a dry etching process used to remove part of the metal stack layer also further remove part of the sacrificial layer. Accordingly, the amount of residual etching gas can be significantly reduced after performing a plasma treatment process on surfaces of the formed gate lines and protruding patterns, thereby avoiding the problems of metal corrosion and photoresist residue. In other words, the pixel array substrate produced by the aforementioned method may have higher process yield and reliability.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A manufacturing method of a pixel array substrate, comprising:
forming a sacrificial layer on a substrate;
forming a metal stack layer on the sacrificial layer, wherein the metal stack layer includes a first titanium layer, an aluminum layer and a second titanium layer;
using a dry etching process to remove part of the metal stack layer and part of the sacrificial layer, and forming a plurality of gate lines and a plurality of protruding patterns, wherein the protruding patterns are respectively aligned with the gate lines; and
performing a plasma treatment process on surfaces of the gate lines and the protruding patterns using a reactive gas.

2. The manufacturing method of the pixel array substrate according to claim 1, wherein the steps of the dry etching process include:
performing a first-stage etching on the metal stack layer and the sacrificial layer using an etching gas and according to first process parameters, wherein the first process parameters include a first bias power and a first etching time; and
performing a second-stage etching on the metal stack layer and the sacrificial layer using the etching gas and according to second process parameters, wherein the second process parameters include a second bias power and a second etching time, the second bias power is less than the first bias power, and the second etching time is less than the first etching time.

3. The manufacturing method of the pixel array substrate according to claim 2, wherein the first process parameters further include a first chamber pressure, the second process parameters further include a second chamber pressure, and the second chamber pressure is less than the first chamber pressure.

4. The manufacturing method of the pixel array substrate according to claim 2, wherein the etching gas includes Cl₂.

5. The manufacturing method of the pixel array substrate according to claim 1, wherein the reactive gas includes CF₄ and O₂.

6. The manufacturing method of the pixel array substrate according to claim 1, wherein a thickness of the sacrificial layer is not less than 250 angstroms.

7. The manufacturing method of the pixel array substrate according to claim 1, wherein the material of the sacrificial layer includes SiNₓ or SiO₂.

8. A pixel array substrate, comprising:
a substrate,
a plurality of gate lines, each including a first titanium layer, an aluminum layer and a second titanium layer sequentially stacked on the substrate; and
a sacrificial layer, disposed between the substrate and each of the gate lines, and having a plurality of protruding patterns aligned with the gate lines.

9. The pixel array substrate according to claim 8, wherein a thickness of the sacrificial layer is not less than 250 angstroms.

10. The pixel array substrate according to claim 8, wherein the sacrificial layer further has a residual portion extending from the protruding patterns, and a percentage of a thickness of the residual portion to a thickness of each of the protruding patterns is less than or equal to 20%.
